(19) United States
(12) Patent Application Publication
(10) Pub. No.: US 2025/0015251 A1
(43) Pub. Date: Jan. 9, 2025

(54) SILICON-CARBON NEGATIVE ELECTRODE MATERIAL FOR LITHIUM-ION BATTERY, METHOD FOR PREPARING THE SAME, AND LITHIUM-ION BATTERY

(71) Applicant: HUNAN ZHONGKE SHINZOOM CO., LTD., Ningxiang Changsha, Huna (CN)

(72) Inventor: Zhiyong WANG, Ningxiang Changsha, Hunan (CN)

(73) Assignee: HUNAN ZHONGKE SHINZOOM CO., LTD., Ningxiang Changsha, Hunan (CN)

(21) Appl. No.: 18/710,053

(22) PCT Filed: Oct. 27, 2022
(86) PCT No.: PCT/CN2022/128002

§ 371 Date: May 14, 2024

(30) Foreign Application Priority Data
Nov. 25, 2021 (CN) 202111411879.5

(51) Int. Cl. H01M 4/04; H01M 4/02; H01M 4/36; H01M 4/38; H01M 4/583; H01M 10/0525

(52) U.S. Cl. CPC H01M 4/0428; H01M 4/0471; H01M 4/364; H01M 4/366; H01M 4/386; H01M 4/583; H01M 10/0525; H01M 2004/021; H01M 2004/027

(57) ABSTRACT

A silicon-carbon negative electrode material for a lithium-ion battery, a method for preparing the same, and a lithium-ion battery are provided. The method includes: forming an oxygen-free environment inside a reactor by fixing a porous carbon-based film material inside the reactor and injecting an inert gas to replace air inside the reactor; obtaining a silicon-carbon negative electrode material precursor by heating and insulating the reactor where the oxygen-free environment is formed and injecting a silane gas for a chemical vapor deposition (CVD) reaction; and obtaining the silicon-carbon negative electrode material for the lithium-ion battery by performing carbon coating, crushing, secondary coating, and carbonization on the silicon-carbon negative electrode material precursor.

### CROSS-REFERENCE TO RELATED APPLICATION(S)

This application is a National Stage of International Application No. PCT/CN2022/128002, filed Oct. 27, 2022, which claims priority to Chinese Patent Application No. 202111411879.5, filed Nov. 25, 2021, the entire disclosures of which are hereby incorporated by reference.

### TECHNICAL FIELD

This application belongs to the field of a negative electrode material for a lithium-ion battery, and particularly to a silicon-carbon negative electrode material for a lithium-ion battery, a method for preparing the same, and a lithium-ion battery.

### BACKGROUND

Lithium-ion batteries have broad application prospects and are in great demand in fields such as mobile electronic devices, electric vehicles, and large-scale energy storage. Negative electrode materials used in traditional lithium-ion battery systems are mainly graphitic materials. However, a theoretical specific capacity of the graphitic materials is relatively low, only 372 mAh·g⁻¹, which is difficult to meet a high-energy-density requirement of new lithium-ion batteries. Therefore, it is crucial to develop a new high-capacity negative electrode material for lithium-ion batteries.

Silicon is regarded as a new generation of lithium-ion battery negative electrode material and has attracted widespread attention and research interest because of its extremely high theoretical specific capacity (4200 mAh/g) and a suitable potential for lithium deintercalation. However, shortcomings of silicon such as low first Coulombic efficiency and poor cycling performance caused by extremely large volume change rate (>300%) of silicon during charge and discharge have become main obstacles to commercial application of silicon-based lithium-ion battery negative electrode materials.

In a traditional method for preparing nano-silicon through chemical vapor deposition (CVD), a silicon source after decomposition easily agglomerates on a material of carbon substrate to form micron-level granular or linear products, resulting in loss of a unique advantage of nano-silicon. Moreover, when a silicon-carbon negative electrode material is prepared with nano-silicon directly, it is difficult for nano-silicon to be evenly dispersed throughout the system, resulting in an excessive expansion rate of an electrode piece during charge and discharge, and further degrading material performances.

CN 104103821 A provides a method for preparing a silicon-carbon negative electrode material. The method includes: 1) placing a catalyst in a CVD reaction chamber; 2) obtaining a silicon-carbon negative electrode material precursor by: heating the CVD reaction chamber, injecting a reaction gas source and a carrier gas into the CVD reaction chamber, and leading Si-Siox generated during the CVD reaction to pass through a carbon matrix which is rotated dynamically and subjected to carboxylation treatment; and 3) obtaining the silicon-carbon negative electrode material by: performing organic pyrolytic carbon coating treatment on the precursor and calcining in a non-oxidizing atmosphere. In this way, nano-silicon with a high specific capacity can be prepared, but the prepared silicon fails to be fully and evenly distributed on all surface interfaces of the carbon matrix, resulting in potential dangers such as deterioration of cycling performance and excessive volume expansion rate of the material.

CN 1903793 A provides a carbon-silicon composite material and a method for preparing the same, and usage thereof. The carbon-silicon composite material includes a silicon matrix, and carbon nanotubes or nanocarbon fibers grown the silicon matrix. The carbon nanotubes or nanocarbon fibers have a straight geometric appearance, or a curved or spiral geometric appearance. The carbon-silicon composite material may be prepared in many ways. A catalyst may be loaded onto a silicon material, or the catalyst and silicon particles are mixed or alloyed, and then the carbon nanotubes or nanocarbon fibers are deposited with a CVD method. Although the surface-grown carbon nanotubes or nanocarbon fibers provided in this way have a large specific surface area and a large porosity, silicon particles fail to be evenly distributed on the surface, and thus, the problem of volume expansion of the silicon particles during cycling fails to be solved.

CN 109449388 A provides a method for preparing a carbon-silicon negative electrode material for a lithium-ion battery. The method includes: (1) obtaining porous carbon by: carbonizing starch and a catalyst under a vacuum condition after the starch and the catalyst are mixed evenly, and then performing washing, drying, grinding, and sieving; (2) adding the porous carbon obtained in operation (1) for mixing after graphite aqueous solution and nano-silicon aqueous solution are mixed, and then drying, grinding, and sieving a mixture; and (3) obtaining the carbon-silicon negative electrode material for the lithium-ion battery by: dissolving an organic carbon source into water, adding a product obtained in operation (2) and concentrated sulfuric acid sequentially, performing insulating, washing, and drying on a mixture liquid after the mixture liquid is stirred, and then performing vacuum carbonization. Such method adopts graphite as a buffer for volume expansion of silicon particles. However, a theoretical specific capacity of graphite materials is relatively low, and it is difficult to meet the high-energy-density requirement of new lithium-ion batteries. Moreover, this method is complicated and is not conducive to industrial production.

Therefore, how to provide a method for preparing an industrialized silicon-based silicon-carbon composite material that can alleviate a problem of volume expansion of silicon during cycling and reduce a production difficulty has become a problem to be solved in this field.

### SUMMARY

The following is a summary of the solutions of the DETAILED DESCRIPTION in the disclosure. This summary is not intended to limit the protection scope of the appended claims.

In a first aspect, the disclosure provides a method for preparing a silicon-carbon negative electrode material for a lithium-ion battery. The method includes: forming an oxygen-free environment inside a reactor by fixing a porous carbon-based film material inside the reactor and injecting an inert gas to replace air inside the reactor; obtaining a silicon-carbon negative electrode material precursor by heating and insulating the reactor where the oxygen-free environment is formed and injecting a silane gas for a chemical vapor deposition (CVD) reaction; and obtaining the silicon-carbon negative electrode material for the lithium-ion battery by performing carbon coating, crushing, secondary coating, and carbonization on the silicon-carbon negative electrode material precursor.

In a second aspect, the disclosure provides a silicon-carbon negative electrode material for a lithium-ion battery. The silicon-carbon negative electrode material is obtained through the method described in the first aspect.

In a third aspect, the disclosure provides a lithium-ion battery. The lithium-ion battery contains a silicon-carbon negative electrode material obtained through the method described in the first aspect.

### DETAILED DESCRIPTION

Hereinafter, technical solutions of the disclosure will be further depicted through exemplary embodiments. Those skilled in the art should understand that embodiments described below are to help understand the disclosure and should not be construed as limiting the disclosure.

In view of the above deficiencies of the related art, the disclosure provides a silicon-carbon negative electrode material for a lithium-ion battery, a method for preparing the same, and a lithium-ion battery. The method can achieve even vapor deposition of nano-silicon particles by adopting a porous carbon-based film material, thereby effectively alleviating a problem of volume expansion of silicon during cycling. Moreover, polarization of the material can be improved effectively through carbon deposition, thereby effectively improving electrochemical performances of the silicon-carbon negative electrode material.

In order to solve the above technical problems, the disclosure adopts the following technical solutions.

In a first aspect, the disclosure provides a method for preparing a silicon-carbon negative electrode material for a lithium-ion battery. The method includes: forming an oxygen-free environment inside a reactor by fixing a porous carbon-based film material inside the reactor and injecting an inert gas to replace air inside the reactor; obtaining a silicon-carbon negative electrode material precursor by heating and insulating (i.e., performing heat preservation) the reactor where the oxygen-free environment is formed and injecting a silane gas for a chemical vapor deposition (CVD) reaction; and obtaining the silicon-carbon negative electrode material for the lithium-ion battery by performing carbon coating, crushing, secondary coating, and carbonization on the silicon-carbon negative electrode material precursor.

In the method for preparing the silicon-carbon negative electrode material for the lithium-ion battery provided in the disclosure, the porous carbon-based film material is used as a substrate, which can achieve even vapor deposition of nano-silicon particles, thereby effectively alleviating the problem of volume expansion of silicon during cycling.

Generally, deposition of the silane gas is not easy to operate. In the disclosure, a pressure difference before and after injecting of the silane gas into the porous carbon-based film material make the silane gas deposit in gaps of the porous carbon-based film material, and the porous carbon-based film material can directionally guide deposition and adsorption of silane molecules inside the gaps by controlling a gas flow direction. As such, when the silane gas passes through the gaps of the porous carbon-based film material, part of the silane gas can be adsorbed inside the gaps effectively.

The reactor is not specifically limited in the disclosure, as long as the reactor can ensure the gas flow to pass through in a directional manner and is a heatable device.

In some embodiments, the porous carbon-based film material includes any one of carbon paper, a carbon nanotube film, or a graphene film.

In some embodiments, the porous carbon-based film material has a thickness of 100 μm to 500 μm, such as 100 μm, 150 μm, 200 μm, 250 μm, 300 μm, 350 μm, 400 μm, 450 μm, or 500 μm, but the thickness of the porous carbon-based film material is not limited to the listed values, other unlisted values within the numerical range are also applicable.

If the thickness of the porous carbon-based film material of the disclosure is too large, there will be a large difference in the amount of silane deposited on front and rear surfaces of the porous carbon-based film material, resulting in uneven deposition. Conversely, if the thickness is too small, when the silane gas passes through at a certain flow rate, the porous carbon-based film material may be penetrated, so that the silane gas fails to be deposited in the porous carbon-based film, resulting in material waste.

In some embodiments, the porous carbon-based film material has a tortuosity of 1.5 to 5, such as 1.5, 2, 2.5, 3, 3.5, 4, 4.5, or 5, but the tortuosity of the porous carbon-based film material is not limited to the listed values, other unlisted values within the numerical range are also applicable.

In some embodiments, the reactor is heated up to 600° C. to 800° C., such as 600° C., 620° C., 640° C., 660° C., 680° C., 700° C., 720° C., 740° C., 760° C., 780° C., or 800° C., but the temperature after heating up is not limited to the listed values, other unlisted values within the numerical range are also applicable.

In some embodiments, a time of the insulating ranges from 0.5 h to 2 h, such as 0.5 h, 0.8 h, 1 h, 1.2 h, 1.4 h, 1.6 h, 1.8 h, or 2 h, but the time of the insulating is not limited to the listed values, other unlisted values within the numerical range are also applicable.

In some embodiments, an angle between a position of the porous carbon-based film material and a flow direction of the silane gas ranges from 600 to 120°, such as 60°, 70°, 80°, 90°, 100°, 110°, or 120°, but the angle is not limited to the listed values, other unlisted values within the numerical range are also applicable.

In some embodiments, the angle between the position of the porous carbon-based film material and the flow direction of the silane gas is 90°.

In the disclosure, the porous carbon-based film material is placed at a certain angle with the flow direction of the silane gas, so that the silane gas can pass through the porous carbon-based film material, which facilitates deposition of silane inside gaps of the porous carbon-based film material.

In some embodiments, a gas flow rate of the silane gas ranges from 0.1 L/min to 2 L/min, such as 0.1 L/min, 0.5 L/min, 1 L/min, 1.5 L/min, or 2 L/min, but the gas flow rate is not limited to the listed values, other unlisted values within the numerical range are also applicable.

In the disclosure, if the gas flow rate of the silane gas is too high, a residence time of the silane gas inside the film material will be reduced, as a result, effective adsorption fails to be achieved. Moreover, an excessive gas flow rate will make the film material of a certain strength unable to withstand or even rupture. In addition, since the film material has a certain degree of tortuosity, which has a certain hindering effect on the gas, if the gas flow rate is too small, the silane gas will not be able to pass through the film and only stay on a surface of the film material.

In some embodiments, a flow time of the silane gas ranges from 2 h to 5 h, such as 2 h, 2.5 h, 3 h, 3.5 h, 4 h, 4.5 h, or 5 h, but the flow time is not limited to the listed values, and other unlisted values within the numerical range are also applicable.

In some embodiments, the carbon coating is performed in an inert gas atmosphere.

In some embodiments, the inert gas includes at least one of helium or argon.

In some embodiments, a temperature of the carbon coating ranges from 800° C. to 1200° C., such as 800° C., 850° C., 900° C., 950° C., 1000° C., 1050° C., 1100° C., 1150° C., or 1200° C., but the temperature of the carbon coating is not limited to the listed values, other unlisted values within the numerical range are also applicable.

In some embodiments, a coating time of the carbon coating ranges from 2 h to 6 h, such as 2 h, 2.5 h, 3 h, 3.5 h, 4 h, 4.5 h, 5 h, 5.5 h, or 6 h, but the coating time is not limited to the listed values, other unlisted values within the numerical range are also applicable.

In some embodiments, a carbon-containing gas source during the carbon coating includes any one or a combination of at least two of methane, ethane, propane, ethylene, propylene, or acetylene. Exemplary combinations include, but not limited to, a combination of methane and ethane, a combination of methane and propane, a combination of methane and ethylene, a combination of methane and propylene, a combination of methane and acetylene, a combination of methane, ethane, and acetylene, or a combination of methane, ethane, propane, ethylene, and acetylene.

In some embodiments, particles obtained after crushing each have an average particle size D50 ranging from 5 μm to 20 μm, such as 5 μm, 8 μm, 10 μm, 12 μm, 14 μm, 16 μm, 18 μm, or 20 μm, but the average particle size is not limited to the listed values, other unlisted values within the numerical range are also applicable.

In some embodiments, a coating material for the secondary coating includes an organic carbon source.

In some embodiments, the organic carbon source includes any one or a combination of at least two of asphalt, tar, or phenolic resin. Exemplary combinations include, but not limited to, a combination of asphalt and tar, a combination of asphalt and phenolic resin, a combination of tar and phenolic resin, or a combination of asphalt, tar, and phenolic resin.

In some embodiments, a coating ratio of the secondary coating ranges from 5% to 20%, such as 5%, 8%, 10%, 12%, 14%, 16%, 18%, or 20%, but the coating ratio is not limited to the listed values, other unlisted values within the numerical range are also applicable.

In some embodiments, a temperature of the carbonization ranges from 800° C. to 1200° C., such as 800° C., 850° C., 900° C., 950° C., 1000° C., 1050° C., 1100° C., 1150° C., or 1200° C., but the temperature of the carbonization is not limited to the listed values, other unlisted values within the numerical range are also applicable.

In some embodiments, a time of the carbonization ranges from 3 h to 10 h, such as 3 h, 4 h, 5 h, 6 h, 7 h, 8 h, 9 h, or 10 h, but the time of the carbonization is not limited to the listed values, other unlisted values within the numerical range are also applicable.

In some embodiments, the method includes: forming the oxygen-free environment inside the reactor by fixing the porous carbon-based film material inside the reactor and injecting the inert gas to replace the air inside the reactor, where the porous carbon-based film material has a thickness of 100 μm to 500 μm and a tortuosity of 1.5 to 5; obtaining the silicon-carbon negative electrode material precursor by: heating up the reactor where the oxygen-free environment is formed to 600° C. to 800° C., performing insulating for 0.5 h to 2 h, injecting the silane gas for 2 h to 5 h at a gas flow rate of 0.1 L/min to 2 L/min for the CVD reaction, and forming nano-silicon particles, where an angle between a flow direction of the silane gas and a position of the porous carbon-based film material ranges from 60° to 120°; and obtaining the silicon-carbon negative electrode material for the lithium-ion battery by: performing carbon coating on the silicon-carbon negative electrode material precursor in an inert gas atmosphere at a temperature of 800° C. to 1200° C. for 2 h to 6 h with a carbon-containing gas source, then performing crushing on the silicon-carbon negative electrode material precursor to obtain particles with an average particle size D50 of 5 μm to 20 μm, performing secondary coating with a coating material, and performing carbonization at 800° C. to 1200° C. for 3 h to 10 h, wherein a coating ratio of the secondary coating ranges from 5% to 20%.

In a second aspect, the disclosure provides a silicon-carbon negative electrode material for a lithium-ion battery. The silicon-carbon negative electrode material is obtained through the method described in the first aspect.

In a third aspect, the disclosure provides a lithium-ion battery. The lithium-ion battery contains a silicon-carbon negative electrode material obtained through the method described in the first aspect.

Each of the numerical ranges described in the disclosure not only includes the values listed above, but also includes any unlisted value within said numerical range. For the sake of space limitation and conciseness, the disclosure does not exhaustively list all specific values in each of the numerical ranges.

Compared with the existing technology, the disclosure has the following advantageous effects.

The method for preparing the silicon-carbon negative electrode material for the lithium-ion battery of the disclosure can achieve even vapor deposition of nano-silicon particles by adopting the porous carbon-based film material, thereby effectively alleviating the problem of volume expansion of silicon during cycling. Moreover, polarization of the material can be improved effectively through carbon deposition, thereby effectively improving electrochemical performances of the silicon-carbon negative electrode material.

### First Embodiment

This embodiment provides a method for preparing a silicon-carbon negative electrode material for a lithium-ion battery. The method includes: (1) forming an oxygen-free environment inside a reactor by fixing carbon paper inside the reactor and injecting helium to replace air inside the reactor, where the carbon paper has a thickness of 250 μm and a tortuosity of 3; (2) obtaining a silicon-carbon negative electrode material precursor by: heating up the reactor where the oxygen-free environment is formed in operation (1) to 700° C., performing insulating for 1.2 h, and injecting a silane gas for 3.5 h at a gas flow rate of 0.5 L/min for a CVD reaction, where an angle between a flow direction of the silane gas and a position of the carbon paper in operation (1) is 90°; and (3) obtaining the silicon-carbon negative electrode material for the lithium-ion battery by: performing carbon coating on the silicon-carbon negative electrode material precursor obtained in operation (2) in helium atmosphere at a temperature of 1000° C. for 4 h with methane, then performing crushing on the silicon-carbon negative electrode material precursor to obtain particles with an average particle size D50 of 10 μm, performing secondary coating with pitch, and performing carbonization at 1000° C., where a coating ratio of the secondary coating is 10%.

### Second Embodiment

This embodiment provides a method for preparing a silicon-carbon negative electrode material for a lithium-ion battery. The method includes: (1) forming an oxygen-free environment inside a reactor by fixing carbon paper inside the reactor and injecting helium to replace air inside the reactor, where the carbon paper has a thickness of 100 μm and a tortuosity of 1.5; (2) obtaining a silicon-carbon negative electrode material precursor by: heating up the reactor where the oxygen-free environment is formed in operation (1) to 600° C., performing insulating for 2 h, and injecting a silane gas for 5 h at a gas flow rate of 0.1 L/min for a CVD reaction, where an angle between a flow direction of the silane gas and a position of the carbon paper in operation (1) is 60°; and (3) obtaining the silicon-carbon negative electrode material for the lithium-ion battery by: performing carbon coating on the silicon-carbon negative electrode material precursor obtained in operation (2) in helium atmosphere at a temperature of 1200° C. for 2 h with acetylene, then performing crushing on the silicon-carbon negative electrode material precursor to obtain particles with an average particle size D50 of 20 μm, performing secondary coating with tar, and performing carbonization at 1200° C. for 3 h, where a coating ratio of the secondary coating is 8%.

### Third Embodiment

This embodiment provides a method for preparing a silicon-carbon negative electrode material for a lithium-ion battery. The method includes: (1) forming an oxygen-free environment inside a reactor by fixing carbon paper inside the reactor and injecting helium to replace air inside the reactor, where the carbon paper has a thickness of 500 μm and a tortuosity of 5; (2) obtaining a silicon-carbon negative electrode material precursor by: heating up the reactor where the oxygen-free environment is formed in operation (1) to 800° C., performing insulating for 0.5 h, and injecting a silane gas for 2 h at a gas flow rate of 2 L/min for a CVD reaction, where an angle between a flow direction of the silane gas and a position of the carbon paper in operation (1) is 120°; and (3) obtaining the silicon-carbon negative electrode material for the lithium-ion battery by: performing carbon coating on the silicon-carbon negative electrode material precursor obtained in operation (2) in helium atmosphere at a temperature of 800° C. for 6 h with a mixed gas of ethane and propane, then performing crushing on the silicon-carbon negative electrode material precursor to obtain particles with an average particle size D50 of 5 μm, performing secondary coating with phenolic resin, and performing carbonization at 800° C. for 10 h, where a coating ratio of the secondary coating is 12%.

### Fourth Embodiment

This embodiment provides a method for preparing a silicon-carbon negative electrode material for a lithium-ion battery. The method includes: (1) forming an oxygen-free environment inside a reactor by fixing carbon paper inside the reactor and injecting helium to replace air inside the reactor, where the carbon paper has a thickness of 300 μm and a tortuosity of 2.7; (2) obtaining a silicon-carbon negative electrode material precursor by: heating up the reactor where the oxygen-free environment is formed in operation (1) to 680° C., performing insulating for 1.6 h, and injecting a silane gas for 4 h at a gas flow rate of 0.8 L/min for a CVD reaction, where an angle between a flow direction of the silane gas and a position of the carbon paper in operation (1) is 85°; and (3) obtaining the silicon-carbon negative electrode material for the lithium-ion battery by: performing carbon coating on the silicon-carbon negative electrode material precursor obtained in operation (2) in helium atmosphere at a temperature of 1050° C. for 3.5 h with a mixed gas of methane and acetylene, then performing crushing on the silicon-carbon negative electrode material precursor to obtain particles with an average particle size D50 of 15 μm, performing secondary coating with pitch, and performing carbonization at 1050° C. for 8 h, where a coating ratio of the secondary coating is 16%.

### Fifth Embodiment

This embodiment provides a method for preparing a silicon-carbon negative electrode material for a lithium-ion battery. Other operations and parameters involved in the method are consistent with those of the first embodiment, except that in operation (1), the carbon paper is replaced with a carbon nanotube film.

### Sixth Embodiment

This embodiment provides a method for preparing a silicon-carbon negative electrode material for a lithium-ion battery. Other operations and parameters involved in the method are consistent with those of the first embodiment, except that in operation (1), the carbon paper is replaced with a graphene film.

### Seventh Embodiment

This embodiment provides a method for preparing a silicon-carbon negative electrode material for a lithium-ion battery. Other operations and parameters involved in the method are consistent with those of the first embodiment, except that in operation (1), the thickness of the carbon paper is changed to 80 μm.

### Eighth Embodiment

This embodiment provides a method for preparing a silicon-carbon negative electrode material for a lithium-ion battery. Other operations and parameters involved in the method are consistent with those of the first embodiment, except that in operation (1), the thickness of the carbon paper is changed to 600 μm.

### Ninth Embodiment

This embodiment provides a method for preparing a silicon-carbon negative electrode material for a lithium-ion battery. Other operations and parameters involved in the method are consistent with those of the first embodiment, except that the angle between the flow direction of the silane gas in operation (2) and the position of the carbon paper in operation (1) is changed to 20°.

### Tenth Embodiment

This embodiment provides a method for preparing a silicon-carbon negative electrode material for a lithium-ion battery. Other operations and parameters involved in the method are consistent with those of the first embodiment, except that the angle between the flow direction of the silane gas in operation (2) and the position of the carbon paper in operation (1) is changed to 0°.

### Eleventh Embodiment

This embodiment provides a method for preparing a silicon-carbon negative electrode material for a lithium-ion battery. Other operations and parameters involved in the method are consistent with those of the first embodiment, except that in operation (2), heating up to 500° C.

### Twelfth Embodiment

This embodiment provides a method for preparing a silicon-carbon negative electrode material for a lithium-ion battery. Other operations and parameters involved in the method are consistent with those of the first embodiment, except that in operation (2), heating up to 900° C.

### First Comparative Embodiment

This comparative embodiment provides a method for preparing a silicon-carbon negative electrode material for a lithium-ion battery. The method includes: preparing silicon particles by: evacuating a CVD equipment, injecting a mixed gas of silane and argon into the CVD equipment, and performing heating at 800° C. for 7 h; and preparing the silicon-carbon negative electrode material by: injecting a mixed gas of acetylene and argon into the CVD equipment, performing heating at 800° C. for 1 h, and preparing a carbon coating layer on surfaces of the silicon particles.

### Second Comparative Embodiment

This comparative embodiment provides a method for preparing a silicon-carbon negative electrode material for a lithium-ion battery. The method includes: (a) obtaining a powder material by: mixing nano-silicon dispersion, conductive additive, and a coating material, dispersing and stirring for 2 h, and perform spray drying; (b) obtaining a silicon-carbon negative electrode material precursor by: heating up to 1000° C. at a heating rate of 3° C./min, performing carbonization heat treatment on the powder material obtained in operation (a) for 6 h, and then crushing; and (c) obtaining the silicon-carbon negative electrode material for the lithium-ion battery by compounding a graphite material with the silicon-carbon negative electrode material precursor obtained in operation (b).

The silicon-carbon negative electrode materials for the lithium-ion battery prepared through the first to twelfth embodiments and the first to second comparative embodiments are applied to lithium-ion batteries, and electrochemical performances of these lithium-ion batteries are tested. The tests are conducted on Wuhan Blue Electric CT2001A battery tester, where a voltage ranges from 0.005V to 1.5V, a rate for capacity test is 0.05C/0.05C, and a rate for cycle test is 0.5C/0.5C. The specific test results are shown in Table 1.

The cycle test of a battery refers to test of a full battery made by matching a ternary positive electrode material with a negative electrode material of 420 mAh/g prepared through mixing of a material and a commercial graphite material. The ternary material (e.g., LiNi_{1/3}Co_{1/3}Mn_{1/3}O₂) is used as a positive electrode, LiPF6 (e.g., solvent: EC+DEC, a volume ratio of 1:1, a concentration of 1.3 mol/l) is used as electrolyte, celegard2400 is used as a separator, to prepare a soft-pack battery.

Full-charge rebound test: first, after the capacity of a soft pack battery is set, disassemble the soft pack battery, and the thickness of a negative electrode plate of the battery is tested to be D1; then, the soft-pack battery is fully charged for 100 times, and disassemble the soft-pack battery, and the thickness of the negative electrode plate of the battery is tested to be D2; finally, calculate the full-charge rebound rate (D2−D1)/D1.

TABLE 1

| | Discharge | | | |
|---|---|---|---|---|
| | specific | First cycle | Full-charge | retention rate |
| | capacity | efficiency | rebound | after 500 |
| | (mAh/g) | (%) | rate (%) | cycles (%) |
| First | 1670 | 91.3 | 31.2 | 93.6 |
| embodiment | | | | |
| Second | 1610 | 91.5 | 32.1 | 93.1 |
| embodiment | | | | |
| Third | 1530 | 92.3 | 30.1 | 92.8 |
| embodiment | | | | |
| Fourth | 1580 | 91.7 | 30.6 | 92.9 |
| embodiment | | | | |
| Fifth | 1690 | 91.0 | 32.3 | 93.5 |
| embodiment | | | | |
| Sixth | 1720 | 90.8 | 32.4 | 93.7 |
| embodiment | | | | |
| Seventh | 1215 | 92.3 | 28.1 | 93.2 |
| embodiment | | | | |
| Eighth | 1123 | 90.6 | 34.8 | 90.1 |
| embodiment | | | | |
| Ninth | 521 | 92.3 | 27.6 | 94.1 |
| embodiment | | | | |
| Tenth | 392 | 92.5 | 26.3 | 93.8 |
| embodiment | | | | |
| Eleventh | 1320 | 92.1 | 30.1 | 93.0 |
| embodiment | | | | |
| Twelfths | 1420 | 91.6 | 31.5 | 92.7 |
| embodiment | | | | |
| First | 2530 | 88.2 | 43.3 | 72 |
| comparative | | | | |
| embodiment | | | | |
| Second | 420 | 89.3 | 38.2 | 85.7 |
| comparative | | | | |
| embodiment | | | | |

As can be seen from Table 1, the silicon-carbon negative electrode material obtained in the disclosure has a high capacity more than 1530 mAh/g, and has a high first cycle efficiency and an excellent cycling performance. Different carbon nanofilm substrates can effectively achieve nano-silicon deposition, thereby ensuring improvement of the cycling performance of the battery. By comparison, it is found that when the thickness of the film material is too small, the film material will be damaged during reaction, so that an adsorption film of the silane gas fails to be formed effectively, resulting in a reduction in a capacity of the material. However, when the thickness of the film material is too large, a gas passing rate will be low, resulting in uneven deposition phenomenon with much silane gas deposited at the front but little silane gas deposited at the back. In addition, too much deposition at the front will also lead to aggregation of silicon nanoparticles, resulting in a decrease in the cycling performance of the battery. By comparison, it is found that when the film material is fixed at a low angle, the silane gas will selectively bypass the film material, so that less deposition on the film material, as a result, preparing of nano-silicon particles on the film material fails, and preparing of the high-capacity silicon-carbon negative electrode material fails to be realized. A relatively high or low pyrolysis reaction temperature is not conducive to deposition of nano-silicon in the material, resulting in a decrease in a capacity of the material.

In sum, the method for preparing the silicon-carbon negative electrode material for the lithium-ion battery provided in the disclosure can achieve even vapor deposition of nano-silicon particles with the porous carbon-based film material, thereby effectively alleviating the problem of volume expansion of silicon during cycling. Moreover, polarization of the material can be improved effectively through carbon deposition, thereby effectively improving electrochemical performances of the silicon-carbon negative electrode material.

The Applicant declares that, while the objectives, technical solutions, and advantageous effects of the disclosure have been described in detail in connection with the exemplary embodiments, it is to be understood that the above is only specific embodiments of the disclosure and is not intended to limit the disclosure. Any modifications, equivalent substitutions, and improvements made without departing from the spirit and scope of the disclosure should be encompassed into the protection scope of the disclosure.

1. A method for preparing a silicon-carbon negative electrode material for a lithium-ion battery, comprising:
forming an oxygen-free environment inside a reactor by fixing a porous carbon-based film material inside the reactor and injecting an inert gas to replace air inside the reactor;
obtaining a silicon-carbon negative electrode material precursor by heating and insulating the reactor where the oxygen-free environment is formed and injecting a silane gas for a chemical vapor deposition (CVD) reaction; and
obtaining the silicon-carbon negative electrode material for the lithium-ion battery by performing carbon coating, crushing, secondary coating, and carbonization on the silicon-carbon negative electrode material precursor.

2. The method of claim 1, wherein the porous carbon-based film material comprises any one of carbon paper, a carbon nanotube film, or a graphene film.

3. The method of claim 1, wherein the reactor is heated up to 600° C. to 800° C.

4. The method of claim 1, wherein an angle between a position of the porous carbon-based film material and a flow direction of the silane gas ranges from 60° to 120°.

5. The method of claim 1, wherein the carbon coating is performed in an inert gas atmosphere.

6. The method of claim 1, wherein particles obtained after crushing each have an average particle size D50 ranging from 5 μm to 20 μm.

7. The method of claim 1, wherein a coating material for the secondary coating comprises an organic carbon source, and the organic carbon source comprises any one or a combination of at least two of pitch, tar, or phenolic resin.

8. The method of claim 1, wherein
forming the oxygen-free environment inside the reactor by fixing the porous carbon-based film material inside the reactor and injecting the inert gas to replace the air inside the reactor comprises:
forming the oxygen-free environment inside the reactor by fixing the porous carbon-based film material inside the reactor and injecting the inert gas to replace the air inside the reactor, wherein the porous carbon-based film material has a thickness of 100 μm to 500 μm and a tortuosity of 1.5 to 5;
obtaining the silicon-carbon negative electrode material precursor by heating and insulating the reactor where the oxygen-free environment is formed and injecting the silane gas for the CVD reaction comprises:
obtaining the silicon-carbon negative electrode material precursor by: heating up the reactor where the oxygen-free environment is formed to 600° C. to 800° C., performing insulating for 0.5 h to 2 h, and injecting the silane gas for 2 h to 5 h at a gas flow rate of 0.1 L/min to 2 L/min for the CVD reaction, wherein an angle between a flow direction of the silane gas and a position of the porous carbon-based film material ranges from 600 to 120°; and
obtaining the silicon-carbon negative electrode material for the lithium-ion battery by performing carbon coating, crushing, secondary coating, and carbonization on the silicon-carbon negative electrode material precursor comprises:
obtaining the silicon-carbon negative electrode material for the lithium-ion battery by: performing carbon coating on the silicon-carbon negative electrode material precursor in an inert gas atmosphere at a temperature of 800° C. to 1200° C. for 2 h to 6 h with a carbon-containing gas source, then performing crushing on the silicon-carbon negative electrode material precursor to obtain particles with an average particle size D50 of 5 μm to 20 μm, performing secondary coating with a coating material, and performing carbonization at 800° C. to 1200° C. for 3 h to 10 h, wherein a coating ratio of the secondary coating ranges from 5% to 20%.

9. A silicon-carbon negative electrode material for a lithium-ion battery, wherein the silicon-carbon negative electrode material is obtained by:
forming an oxygen-free environment inside a reactor by fixing a porous carbon-based film material inside the reactor and injecting an inert gas to replace air inside the reactor;
obtaining a silicon-carbon negative electrode material precursor by heating and insulating the reactor where the oxygen-free environment is formed and injecting a silane gas for a chemical vapor deposition (CVD) reaction; and
obtaining the silicon-carbon negative electrode material for the lithium-ion battery by performing carbon coating, crushing, secondary coating, and carbonization on the silicon-carbon negative electrode material precursor.

10. A lithium-ion battery, containing a silicon-carbon negative electrode material obtained by:
forming an oxygen-free environment inside a reactor by fixing a porous carbon-based film material inside the reactor and injecting an inert gas to replace air inside the reactor;
obtaining a silicon-carbon negative electrode material precursor by heating and insulating the reactor where the oxygen-free environment is formed and injecting a silane gas for a chemical vapor deposition (CVD) reaction; and
obtaining the silicon-carbon negative electrode material for the lithium-ion battery by performing carbon coating, crushing, secondary coating, and carbonization on the silicon-carbon negative electrode material precursor.

11. The method of claim 1, wherein the porous carbon-based film material has a thickness of 100 μm to 500 μm.

12. The method of claim 1, wherein the porous carbon-based film material has a tortuosity of 1.5 to 5.

13. The method of claim 1, wherein a time of the insulating ranges from 0.5 h to 2 h.

14. The method of claim 1, wherein an angle between a position of the porous carbon-based film material and a flow direction of the silane gas is 90°.

15. The method of claim 1, wherein a gas flow rate of the silane gas ranges from 0.1 L/min to 2 L/min, and a flow time of the silane gas ranges from 2 h to 5 h.

16. The method of claim 5, wherein the inert gas comprises at least one of helium or argon.

17. The method of claim 1, wherein a temperature of the carbon coating ranges from 800° C. to 1200° C., and a coating time of the carbon coating ranges from 2 h to 6 h.

18. The method of claim 1, wherein a carbon-containing gas source in a carbon coating process comprises any one or a combination of at least two of methane, ethane, propane, ethylene, propylene, or acetylene.

19. The method of claim 1, wherein a coating ratio of the secondary coating ranges from 5% to 20%.

20. The method of claim 1, wherein a temperature of the carbonization ranges from 800° C. to 1200° C., and a time of the carbonization ranges from 3 h to 10 h.
